(19) United States
(12) Patent Application Publication
(10) Pub. No.: US 2006/0261439 A1
(43) Pub. Date: Nov. 23, 2006

(54) CAPACITOR STRUCTURE

(76) Inventors: Chih-Fu Chien, Taipei City (TW); Chao-Chi Lee, Taipei City (TW); Cheng-Chung Chou, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/908,552

(22) Filed: May 17, 2005

(51) Int. Cl. H01L 29/00

(52) U.S. Cl. 257/532

(57) ABSTRACT

A capacitor structure including a first electrode set and a second electrode set is provided. The first electrode set comprises a plurality of first stripe electrodes, which are parallel to each other, and a first coupling circuit. The first coupling circuit is coupled to a part of stripe electrodes, wherein the coupled first stripe electrodes and the uncoupled first stripe electrodes are alternately arranged. In addition, the second electrode set comprises a plurality of second stripe electrodes, which are parallel to each other, and a second coupling circuit. The second coupling circuit is coupled to a part of the second stripe electrodes, wherein the coupled second stripe electrodes and the uncoupled second stripe electrodes are alternately arranged. Furthermore, the coupled first stripe electrodes are coupled to the coupled second stripe electrodes, and the uncoupled first stripe electrodes are coupled to the uncoupled second stripe electrodes.

### BACKGROUND OF THE INVENTION

1. Field of the Invention

The present invention relates to a capacitor structure, and more particularly to a capacitor structure with better space utility and high efficiency.

2. Description of the Related Art

A capacitor is an essential structure in an integrated circuit. In the design and manufacturing process of a capacitor, capacitance and capacitor area are important factors. As a result, a capacitor with better design and efficient manufacturing process is always sought after.

For example, a memory cell of a dynamic random access memory (DRAM) comprises a transistor and a capacitor for storing bit-sized data, serving as a memory device. Wherein, by selectively charging or discharging each capacitor of the capacitor array on the semiconductor substrate, the data can be stored in the memory. For the memory capacitor with a constant operational voltage, when the space between the electrodes and the dielectric constant of the dielectric material are fixed, the area of the capacitor electrodes determines the capacitance of the capacitor.

FIG. 1 is a schematic drawing showing a conventional plate capacitor structure. Referring to FIG. 1, the plate capacitor structure 100 comprises a top electrode plate 110 and a bottom electrode plate 120, and a dielectric layer 130 between the top electrode plate 110 and the bottom electrode plate 120. Wherein, the top electrode plate 110 and the bottom electrode plate 120 are parallel with a distance d. The conventional plate capacitor structure 100 uses the electrical field generated by the top electrode plate 110 and the bottom electrode plate 120 to obtain the desired capacitance, i.e., the parallel plate capacitance. Thus, the capacitance of the plate capacitor structure 100 is proportional to the area of the top electrode plate 110 and the bottom electrode plate 120.

With the advanced semiconductor technology, the integrated circuits have developed to more miniaturized with high level of integration. The conventional plate capacitor structure requires a great layout area, and cannot meet the requirement of high density of integration in the circuits. In other words, if the conventional plate capacitor structure is used in the DRAM, the miniaturized memory size will cause the area of the top and the bottom electrodes to reduce. As a result, the capacitance of the capacitor is reduced, which may lead to storage error.

Accordingly, a capacitor structure with high density of integration and high capacitance is desired, which has increased surface area of the electrodes to enhance the performance of the capacitor even though the area of the capacitor is reduced.

### SUMMARY OF THE INVENTION

Accordingly, the present invention is directed to a high-performance capacitor structure capable of providing higher capacitance in a relatively small layout area.

The present invention is also directed to a capacitor structure capable of improving space utility to enhance the flexibility of circuit design.

The present invention is also directed to a capacitor structure, which has lower manufacturing costs and higher manufacturing yields.

According to the objects described above, the present invention provides a capacitor structure. The structure is configured in a substrate. The capacitor structure comprises a first electrode set, and a second electrode set. The first electrode set comprises a plurality of first stripe electrodes and a first coupling circuit, wherein the first stripe electrodes are parallel to each other, the first coupling circuit is coupled to a part of the first stripe electrodes, and the coupled first stripe electrodes and the uncoupled first stripe electrodes are alternately arranged. The second electrode set and the first electrode set are in different layers of the substrate. The second set electrode comprises a plurality of second stripe electrodes and a second coupling circuit. Wherein, the second stripe electrodes are parallel to each other, the second coupling circuit is coupled to a part of the second stripe electrodes, and the coupled second stripe electrodes and the uncoupled second stripe electrodes are alternately arranged. The coupled second stripe electrodes are further coupled to the coupled first stripe electrodes. The uncoupled second stripe electrodes are coupled to the uncoupled first stripe electrodes. The coupled first stripe electrodes and the coupled second stripe electrodes have a first potential. The uncoupled first stripe electrodes and the uncoupled second stripe electrodes have a second potential. The first potential is opposite to the second potential.

In an embodiment of the present invention, the first coupling circuit can be disposed at two edges of the first stripe electrodes, for example. The first stripe electrodes and the coupled first coupling circuit constitute a first electrode structure. In addition, the second coupling circuit can be disposed at two edges of the second stripe electrodes, for example. The second stripe electrodes and the coupled second coupling circuit constitute a second electrode structure. The first electrode structure and the second electrode structure can be, for example, of the shape of a net or a zigzag. The capacitor structure of the present invention further comprises at least one first conductive plug and a plurality of second conductive plugs, which are disposed between the first electrode and the second electrode set. The first conductive plug electrically connects the first electrode structure and the second electrode structure. The second conductive plugs electrically connect the uncoupled first stripe electrodes and the uncoupled second stripe electrodes.

In an embodiment of the present invention, the first coupling circuit can be disposed at an edge of the first stripe electrodes, for example. The first stripe electrodes and the coupled first coupling circuit constitute a first electrode structure. In addition, the second coupling circuit can be disposed at an edge of the second stripe electrodes, for example. The second stripe electrodes and the coupled second coupling circuit constitute a second electrode structure. The first electrode structure and the second electrode structure can take the shape as a comb, for example. The capacitor structure of the present invention further comprises at least one first conductive plug and a plurality of second conductive plugs, which are disposed between the first electrode and the second electrode set. The first conductive plug is used to electrically connect the first electrode structure and a second electrode structure. The second conductive plugs electrically connect the uncoupled first stripe electrodes and the uncoupled second stripe electrodes.

From the descriptions above, the first electrode set may further comprise a third coupling circuit. The third coupling circuit and the first coupling circuit are separately on two edges of the first stripe electrodes, and the third coupling circuit is coupled to the first stripe electrodes, which are not coupled to the first coupling circuit, to constitute a third electrode structure. In addition, the second electrode set may further comprise a fourth coupling circuit. The fourth coupling circuit and the second coupling circuit are separately on two edges of the second stripe electrodes, and the fourth coupling circuit is coupled to the second stripe electrodes, which are not coupled to the second coupling circuit, to constitute a fourth electrode structure. The third electrode structure and the fourth electrode structure can take a comb shape, for example. Accordingly, the capacitor structure of the present invention can use at lease a second conductive plug to electrically connect the third electrode structure and the fourth electrode structure. According to an embodiment of the present invention, the substrate can be a wafer or a circuit board.

Accordingly, in the present invention, the first coupling circuit and the second coupling circuit electrically connect the first stripe electrodes and the second stripe electrodes. Thus, the number of the conductive plugs can be reduced so as to reduce the manufacturing costs and to increase the manufacturing yields. In addition, the stripe electrodes of the present invention can generate the fringe capacitance effect to enhance the whole capacitance of the capacitor structure. The stripe electrodes can be integrated with other devices of an integrated circuit during manufacturing. Therefore, the design of the circuit can be more flexible.

The above and other features of the present invention will be better understood from the following detailed description of the preferred embodiments of the invention that is provided in communication with the accompanying drawings.

### BRIEF DESCRIPTION OF THE DRAWINGS

FIG. 1 is a schematic drawing showing a conventional plate capacitor structure.

FIG. 2 is a drawing showing a 3-D capacitor structure according to the first embodiment of the present invention.

FIG. 3 is a drawing showing a 3-D capacitor structure according to a second embodiment of the present invention.

FIG. 4 is a drawing showing a 3-D capacitor structure according to a third embodiment of the present invention.

FIG. 5 is a drawing showing a 3-D capacitor structure according to a fourth embodiment of the present invention.

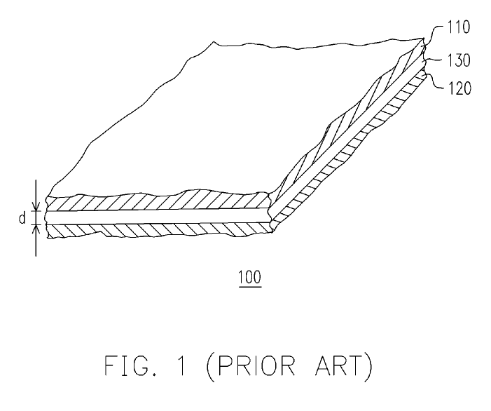

### DESCRIPTION OF SOME EMBODIMENTS

### First Embodiment

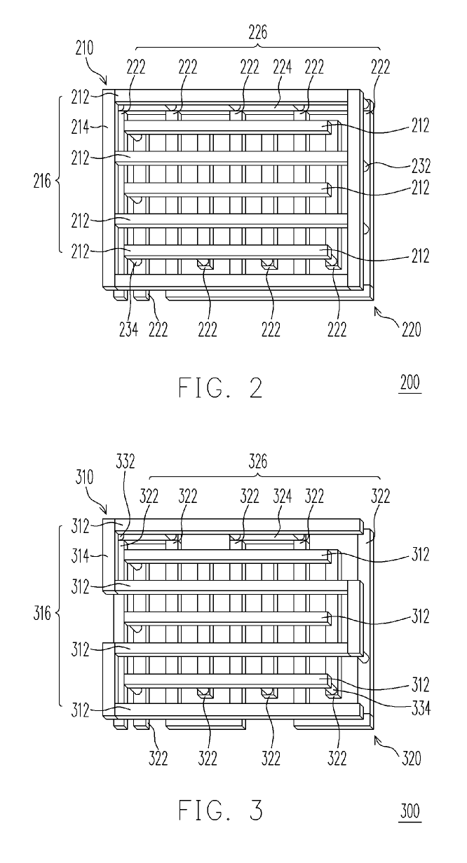

FIG. 2 is a drawing showing a 3-D capacitor structure according to the first embodiment of the present invention. In order to clearly describe the capacitor structure, other layer structures in the substrate are not shown in FIG. 2. Referring to FIG. 2, the capacitor structure 200 is configured in a substrate (not shown). The substrate can be, for example, a wafer, a circuit board, or other circuit substrates. In addition, the capacitor structure 200 comprises a first electrode set 210 and a second electrode set 220. The first electrode set 210 and the second electrode set 220 are in different layers of the substrate (not shown). For example, the first electrode set 210 is on a top surface of a dielectric layer in the substrate (not shown). And, the second electrode set 220 is on a bottom surface of the dielectric layer in the substrate (not shown).

Referring to FIG. 2, the first electrode set 210 comprises a plurality of first stripe electrodes 212 and a first coupling circuit 214, wherein the first stripe electrodes 212 are parallel to each other, and the first coupling circuit 214 is disposed, for example, at two edges of the first stripe electrodes 212. The first coupling circuit 214 is coupled to a part of the first stripe electrodes 212 to constitute a net-shaped first electrode structure 216. The coupled first stripe electrodes 212 and the uncoupled first stripe electrodes 212 are alternately arranged. In addition, the second electrode set 220 comprises a plurality of second stripe electrodes 222 and a second coupling circuit 224. The second stripe electrodes 222 are parallel to each other, and the second coupling circuit 224 is disposed, for example, at two edges of the second stripe electrodes 222. The second coupling circuit 224 is coupled to a part of the second stripe electrodes 222 to constitute a net-shaped second electrode structure 226. The coupled second stripe electrodes 222 and the uncoupled second stripe electrodes 222 are alternately arranged.

In this embodiment, the first electrode structure 216 is coupled to the second electrode structure 226 through at least one first conductive plug 232 in the dielectric layer (not shown), for example. The uncoupled first stripe electrodes 212 are coupled to the uncoupled second stripe electrodes 222 through a plurality of second conductive plugs 234 in the dielectric layer (not shown), for example. The coupled first stripe electrodes 212 and the coupled second stripe electrodes 222 have a first potential. The uncoupled first stripe electrodes 212 and the uncoupled second stripe electrodes 222 have a second potential. The first potential is opposite to the second potential, such as a cathode and an anode to form the capacitor structure 200 of this embodiment. The first stripe electrodes 212 and the first coupling circuit 214 of the first electrode set 210 are on the same layer of the substrate (not shown). The second stripe electrodes 222 and the second coupling circuit 224 of the second electrode set 220 are on another same layer of the substrate (not shown). Accordingly, the pattern of the circuit can be precisely controlled, and a stable capacitance can be provided.

The capacitor structure of the present invention uses the stripe electrodes, which can generate better fringe capacitance effect and enhance the whole capacitance. In addition, the shape of the stripe electrodes of the present invention can be easily incorporated with other devices in the integrated circuit. Therefore, the circuit design can be more flexible. The present invention also uses the coupling circuits to connect part of the stripe electrodes. Thus, the number of conductive plugs can be reduced and the misalignment of the conductive plugs and circuit layers can be avoided. Accordingly, the manufacturing yields can be increased and the manufacturing costs would decline.

In addition to the first embodiment described above, in the present invention, the connection of the coupling circuits can be modified to form different capacitor structures. Different embodiments are as follows. In these embodiments, only part of structure is described. The similar components and connection of the capacitor structure are not repeated. The capacitor structures of these embodiments also have the advantages of high capacitance, few conductive plugs, and high integration with other devices.

### Second Embodiment

FIG. 3 is a drawing showing a 3-D capacitor structure according to a second embodiment of the present invention. Referring to FIG. 3, the first coupling circuit 314 is disposed at two edges of the stripe electrodes 312, but is coupled to every other first stripe electrodes 312 to form a first zigzag electrode structure 316. The coupled first stripe electrodes 312 and the uncoupled first stripe electrodes 312 are alternately arranged. The second coupling circuit 324 is disposed at two edges of the stripe electrodes 322, but is coupled to every other second stripe electrodes 322 to form a second zigzag electrode structure 326. The coupled second stripe electrodes 322 and the uncoupled second stripe electrodes 322 are alternately arranged.

In this embodiment, the first electrode structure 316 is coupled to the second electrode structure 326 through at least one first conductive plug 332, for example. The uncoupled first stripe electrodes 312 are coupled to the uncoupled second stripe electrodes 322 through a plurality of second conductive plugs 334, for example. The coupled first stripe electrodes 312 and the coupled second stripe electrodes 322 have a first potential. The uncoupled first stripe electrodes 312 and the uncoupled second stripe electrodes 322 have a second potential. The first potential is opposite to the second potential, such as a cathode and an anode to constitute the capacitor structure 300 of this embodiment.

### Third Embodiment

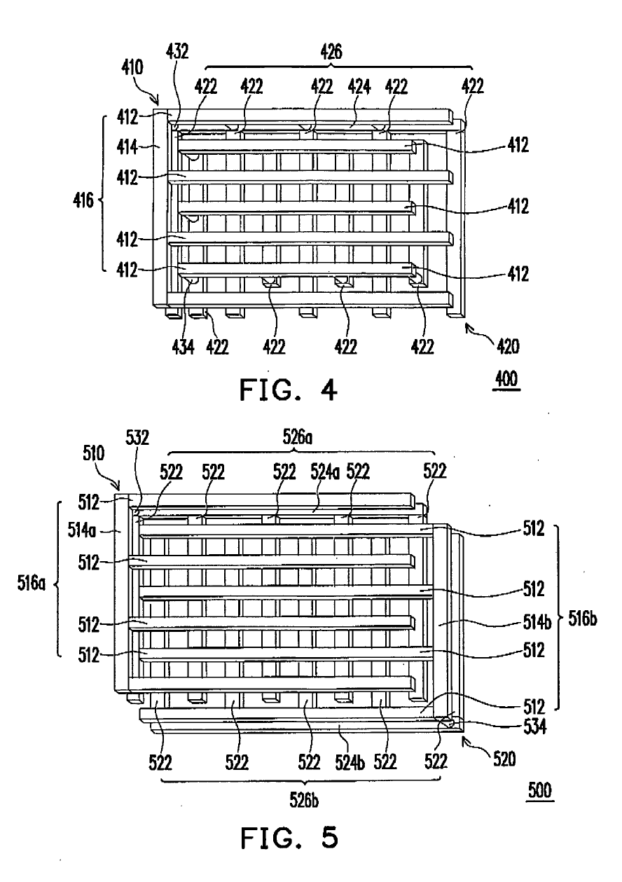

FIG. 4 is a drawing showing a 3-D capacitor structure according to a third embodiment of the present invention. Referring to FIG. 4, the first coupling circuit 414 is disposed at an edge of the stripe electrodes 412, and is coupled to a part of the first stripe electrodes 412 to form a first comb-shaped electrode structure 416. The coupled first stripe electrodes 412 and the uncoupled first stripe electrodes 412 are alternately arranged. The second coupling circuit 424 is disposed, for example, at an edge of the stripe electrodes 322, and is coupled to a part of the second stripe electrodes 422 to form a second comb-shaped electrode structure 426. The coupled second stripe electrodes 422 and the uncoupled second stripe electrodes 422 are alternately arranged.

In this embodiment, the first comb-shaped electrode structure 416 and the second comb-shaped electrode structure 426 are coupled to each other through at least one first conductive plug 432. The uncoupled first stripe electrodes 412 and the uncoupled second stripe electrodes 422 are coupled to each other through a plurality of second conductive plugs 434. Note that the coupled first stripe electrodes 412 and the coupled second stripe electrodes 422 have a first potential. The uncoupled first stripe electrodes 412 and the uncoupled second stripe electrodes 422 have a second potential. The first potential is opposite to the second potential, such as a cathode and an anode to constitute the capacitor structure 400 of this embodiment.

### Fourth Embodiment

FIG. 5 is a drawing showing a 3-D capacitor structure according to a fourth embodiment of the present invention. Referring to FIG. 5, the capacitor structure 500 comprises a first electrode set 510 and a second electrode set 520, wherein the first electrode set 510 comprises a plurality of first stripe electrodes 512, a first coupling circuit 514a and a third coupling circuit 514b. The first stripe electrodes 512 are parallel to each other. The first coupling circuit 514a and the third coupling circuit 514b are separately disposed on two edges of the first stripe electrodes 512. The first coupling circuit 514a and the third coupling circuit 514b are separately coupled to different first stripe electrodes 512 to constitute a first comb-shaped electrode structure 516a and a third comb-shaped electrode structure 516b. In this embodiment, the first stripe electrodes 512 of the first comb-shaped capacitor structure 516a and the first stripe electrodes 512 of the third comb-shaped capacitor structure 516b are alternately arranged.

In addition, the second electrode set 520 comprises a plurality of second stripe electrodes 522, a second coupling circuit 524a and a fourth coupling circuit 524b. The second stripe electrodes 522 are parallel to each other. The second coupling circuit 524a and the fourth coupling circuit 524b are separately disposed on two edges of the second stripe electrodes 522. The second coupling circuit 524a and the fourth coupling circuit 524b are separately coupled to different second stripe electrodes 522 to constitute a second comb-shaped electrode structure 526a and a fourth comb-shaped electrode structure 526b. In this embodiment, the second stripe electrodes 522 of the second comb-shaped capacitor structure 526a and the second stripe electrodes 522 of the fourth comb-shaped capacitor structure 526b are alternately arranged.

The first comb-shaped electrode structure 516a and the second comb-shaped electrode structure 526a are coupled to each other through, for example, at least one first conductive plug 532. The third comb-shaped electrode structure 516b and the fourth comb-shaped electrode structure 526b are coupled to each other through, for example, at least one second conductive plug 534. In addition, the first comb-shaped electrode structure 516a and the second comb-shaped electrode structure 526a have a first potential, and the third comb-shaped electrode structure 516b and the fourth comb-shaped electrode structure 526b have a second potential. The first potential is opposite to the second potential, such as a cathode and an anode to constitute the capacitor structure 500 of this embodiment.

Note that in the embodiments described above, capacitor structures with a double-layer electrode are provided, but the capacitor structure of the present invention can comprise a structure having more than two stacked electrode sets. Moreover, the capacitor structures described above are embodiments of the present invention. The present invention, however, is not limited thereto. Based on these embodiments of the present invention, the connection of the stripe electrodes and the coupling circuits can be modified in any reasonable method and in any shape. After reading the embodiments of the present invention, one of ordinary skill in the art can easily understand the feature of the present invention and modify the structure and connection.

Accordingly, the capacitor structure of the present invention has at least the following advantages.

1. The stripe electrodes have better fringe capacitance effect and can provide a higher capacitance.

2. The stripe electrodes may extend in any direction. The stripe electrodes can be easily integrated with other devices in the integrated circuit. The design of the circuit becomes more flexible.

3. The present invention uses the coupling circuit to connect the stripe electrodes. Accordingly, the number of the conductive plugs can be reduced, and the misalignment of the conductive plugs and the circuit layer can be avoided. The manufacturing yields are enhanced and the manufacturing costs are reduced.

4. The electrode set and the coupling circuit are on the same layer of the substrate. Therefore, the circuit pattern can be precisely controlled and better efficiency can be provided.

Although the present invention has been described in terms of exemplary embodiments, it is not limited thereto. Rather, the appended claims should be constructed broadly to include other variants and embodiments of the invention which may be made by those skilled in the field of this art without departing from the scope and range of equivalents of the invention.

1. A capacitor structure configured in a substrate, the capacitor structure comprising:
a first electrode set comprising a plurality of first stripe electrodes and a first coupling circuit, wherein the first stripe electrodes are parallel to each other, the first coupling circuit is coupled to a part of the first stripe electrodes, and the coupled first stripe electrodes and the uncoupled first stripe electrodes are alternately arranged; and
a second electrode set, the second electrode set and the first electrode set being in different layers, the second set electrode comprising a plurality of second stripe electrodes and a second coupling circuit, wherein the second stripe electrodes are parallel to each other, the second coupling circuit is coupled to a part of the second stripe electrodes, the coupled second stripe electrodes and the uncoupled second stripe electrodes are alternately arranged, the coupled second stripe electrodes are coupled to the coupled first stripe electrodes, the uncoupled second stripe electrodes are coupled to the uncoupled first stripe electrodes, the coupled first stripe electrodes and the coupled second stripe electrodes have a first potential, the uncoupled first stripe electrodes and the uncoupled second stripe electrodes have a second potential, and the first potential is opposite to the second potential,
wherein the first stripe electrodes extend in a direction substantially perpendicular with a direction in which the second stripe electrodes extend.

2. The capacitor structure of claim 1, wherein the first coupling circuit is disposed at two edges of the first stripe electrodes, and the coupled first stripe electrodes and the first coupling circuit constitute a first electrode structure.

3. The capacitor structure of claim 2, wherein the first electrode structure takes the shape of a net or a zigzag.

4. The capacitor structure of claim 2, wherein the second coupling circuit is disposed at two edges of the second stripe electrodes, and the coupled second stripe electrodes and the second coupling circuit constitute a second electrode structure.

5. The capacitor structure of claim 4, wherein the second electrode structure takes the shape of a net or a zigzag.

6. The capacitor structure of claim 4, further comprising at least one first conductive plug, which is disposed between the first electrode set and the second electrode set to electrically connect the first electrode structure and the second electrode structure.

7. The capacitor structure of claim 4, further comprising a plurality of second conductive plugs, which are disposed between the first electrode set and the second electrode set to electrically connect the uncoupled first stripe electrodes and the uncoupled second stripe electrodes.

8. The capacitor structure of claim 1, wherein the first coupling circuit is disposed at an edge of the first stripe electrodes, and the first stripe electrodes and the first coupling circuit constitute a first electrode structure.

9. The capacitor structure of claim 8, wherein the first electrode structure takes a comb shape.

10. The capacitor structure of claim 8, wherein the second coupling circuit is disposed at an edge of the second stripe electrodes, and the coupled second stripe electrodes and the second coupling circuit constitute a second electrode structure.

11. The capacitor structure of claim 10, wherein the second electrode structure takes a comb shape.

12. The capacitor structure of claim 10, further comprising at least one first conductive plug, which is disposed between the first electrode set and the second electrode set to electrically connect the first electrode structure and the second electrode structure.

13. The capacitor structure of claim 10, further comprising a plurality of second conductive plugs, which are disposed between the first electrode set and the second electrode set to electrically connect the uncoupled first stripe electrodes and the uncoupled second stripe electrodes.

14. The capacitor structure of claim 10, wherein the first electrode set further comprises a third coupling circuit, the third coupling circuit and the first coupling circuit are separately on two edges of the first stripe electrodes, and the third coupling circuit is coupled to the first stripe electrodes, which are not coupled to the first coupling circuit to constitute a third electrode structure.

15. The capacitor structure of claim 14, wherein the third electrode structure takes a comb shape.

16. The capacitor structure of claim 14, wherein the second electrode set further comprises a fourth coupling circuit, the fourth coupling circuit and the second coupling circuit are separately on two edges of the second stripe electrodes, and the fourth coupling circuit is coupled to the second stripe electrodes, which are not coupled to the second coupling circuit to constitute a fourth electrode structure.

17. The capacitor structure of claim 16, wherein the fourth electrode structure takes a comb shape.

18. The capacitor structure of claim 16, further comprising at least one first conductive plug, which is disposed between the first electrode set and the second electrode set to electrically connect the first electrode structure and the second electrode structure.

19. The capacitor structure of claim 16, further comprising at least one second conductive plug, which is disposed between the first electrode set and the second electrode set to electrically connect the third electrode structure and the fourth electrode structure.

20. The capacitor structure of claim 1, wherein the substrate is a wafer or a circuit board.
